(19) United States
(12) Patent Application Publication
(10) Pub. No.: US 2023/0178398 A1
(43) Pub. Date: Jun. 8, 2023

(54) METHOD AND DEVICE FOR DEPOSITING AN EPITAXIAL LAYER ON A SUBSTRATE WAFER MADE OF SEMICONDUCTOR MATERIAL

(71) Applicant: SILTRONIC AG, Munich (DE)

(72) Inventors: Thomas STETTNER, Waging am See (DE); Walter EDMAIER, Wittibreut (DE); Korbinian LICHTENEGGER, Munich (DE); Hannes HECHT, Burghausen (DE)

(73) Assignee: SILTRONIC AG, Munich (DE)

(21) Appl. No.: 17/920,211

(22) PCT Filed: Apr. 14, 2021
(86) PCT No.: PCT/EP2021/059668

§ 371 Date: Oct. 20, 2022

(30) Foreign Application Priority Data
Apr. 27, 2020 (EP) 20171534.9

(51) Int. Cl. H01L 21/67; H01L 21/687; C30B 25/12; C30B 25/16

(52) U.S. Cl. CPC H01L 21/67259; H01L 21/68714; C30B 25/12; C30B 25/16

(57) ABSTRACT

A method and an apparatus for depositing an epitaxial layer on a substrate wafer made of semiconductor material. The method comprises the arrangement of the substrate wafer and a susceptor in a deposition device such that the substrate wafer rests on the susceptor and the susceptor is held by arms of a support shaft; monitoring whether a misalignment of the susceptor exists with respect to its position relative to the position of a pre-heating ring surrounding it; monitoring whether a misalignment of the support shaft exists with respect to its position relative to the position of the pre-heating ring; if at least one of the misalignments is present, elimination of the respective misalignment; and the deposition of the epitaxial layer on the substrate wafer.

### CROSS REFERENCE TO RELATED APPLICATIONS

This application is the U.S. National Phase of PCT Appln. No. PCT/EP2021/059668 filed Apr. 14, 2021, which claims priority to European Application No. 20171534.9, filed Apr. 27, 2020, the disclosures of which are incorporated in their entirety by reference herein.

### BACKGROUND OF THE INVENTION

### 1 Field of the Invention

The subject matter of the invention is a method for depositing an epitaxial layer on a substrate wafer made of semiconductor material, and an apparatus for carrying out the method.

### 2. Description of the Related Art

Semiconductor wafers with an epitaxial layer are products required for particularly demanding applications in the electronics industry. Accordingly, the requirements on the epitaxial layer with regard to the uniformity of its thickness and the uniformity of the distribution of dopants in the epitaxial layer are particularly challenging. There is therefore a strong incentive to create production conditions that allow semiconductor wafers with an epitaxial layer satisfying the exacting requirements to be produced with high yields.

The deposition of the epitaxial layer on a semiconductor wafer substrate is usually performed using CVD (chemical vapor deposition) in a deposition device that can receive a substrate wafer. During the deposition of the epitaxial layer, the substrate wafer is located on a susceptor, which is held by support arms of a support shaft and rotated by the support shaft, with a deposition gas being directed over a free upper surface, the front face of the substrate wafer. The deposition device usually also has a pre-heating ring, which is arranged around the susceptor, separated by a gap. An upper and a lower dome define a reaction chamber, within which the epitaxial layer is deposited on the substrate wafer. Radiant heat from banks of lamps is irradiated through the domes to provide a necessary deposition temperature. Deposition devices having these characteristics are available commercially. In addition, it may be provided to load the substrate wafer into the deposition device and place it on the susceptor there, or to load the susceptor with the substrate wafer placed on it into the deposition device, as described in US2018 0 282 900 A1, for example.

It has long been known that a misalignment of the substrate wafer relative to the position of the susceptor can have an adverse effect on the yield. Usually, the substrate wafer should be positioned centrally on the susceptor, so that the circumferential lines of the substrate wafer and the susceptor form concentric circles.

JP2017-69 414 A describes how the position of the substrate wafer on the susceptor is monitored by means of a camera system and, if necessary, the susceptor support shaft is moved horizontally to center a substrate wafer on the susceptor.

US2009 0 314 205 A1 deals with details of an observation system that can monitor the position of the preheating ring, among other functions.

US2016 0 125 589 A1 describes a method that can be used to detect misalignments.

The inventors of the present invention have found that losses in yield can occur due to the presence of particles, due to uneven thickness of the epitaxial layer and due to uneven dopant distribution in the epitaxial layer, which cannot be attributed to a misalignment of the substrate wafer with respect to its position relative to the position of the susceptor.

The object of the present invention is to indicate the reason for such losses of yield and to show how they can be remedied.

### SUMMARY OF THE INVENTION

One or more objects of the invention are achieved by a method for depositing an epitaxial layer on a substrate wafer of semiconductor material, comprising the arrangement of the substrate plate and a susceptor in a deposition device such that the substrate wafer rests on the susceptor and the susceptor is held by arms of a support shaft;

monitoring whether a misalignment of the susceptor exists with respect to its position relative to the position of a pre-heating ring surrounding it; monitoring whether a misalignment of the support shaft exists with respect to its position relative to the position of the pre-heating ring;
if at least one of the misalignments is present, elimination of the respective misalignment; and deposition of the epitaxial layer on the substrate wafer.

### BRIEF DESCRIPTION OF THE DRAWINGS

FIG. 1 shows an exemplary embodiment of a deposition device having features according to the invention.

FIG. 2 shows the observation of the gap between the susceptor and the pre-heating ring.

### DETAILED DESCRIPTION OF THE PREFERRED EMBODIMENTS

The objects of the invention are additionally achieved by an apparatus for depositing an epitaxial layer on a substrate wafer made of semiconductor material, comprising a susceptor, a pre-heating ring, a support shaft with susceptor support arms,

a camera system for monitoring the width of a section of a gap between the susceptor and the pre-heating ring and a distance from the camera system to the susceptor,
an image processing device for determining the presence of a misalignment of the susceptor with respect to its position relative to the position of the pre-heating ring and/or a misalignment of the support shaft with respect to its position relative to the position of the pre-heating ring, a drive unit for moving and tilting the susceptor support shaft, and a control device for generating a signal in the event of a misalignment, wherein the signal causes the drive unit to move in a manner that corrects the existing misalignment.

The inventors have discovered that the yield losses mentioned can be attributed to the presence of misalignments with respect to the position of the susceptor and/or with respect to the position of the support shaft thereof relative to the position of the pre-heating ring. Between the pre-heating ring and the susceptor a gap is usually provided that has the same width along the inner circumference of the pre-heating ring. The pre-heating ring and the susceptor are arranged concentrically to each other and the susceptor is arranged horizontally. The support shaft is aligned along the vertical axis through the center of the pre-heating ring.

A misalignment of the susceptor is therefore present if the susceptor is located eccentrically with respect to the pre-heating ring on the support arms of the support shaft, or if the susceptor is tilted out of the horizontal plain on the support arms of the support shaft. A misalignment of the support shaft relative to the position of the pre-heating ring is present if the support shaft is vertical, but not aligned along the vertical axis through the center of the pre-heating ring, or because the support shaft is tilted out of the vertical axis through the center of the pre-heating ring.

If the susceptor touches the pre-heating ring, particles are produced which act as impurities, making the resulting semiconductor wafer with epitaxial layer unusable for the intended purpose. Losses of yield may also occur if the width of the gap between the pre-heating ring and the susceptor varies along the inner circumference of the pre-heating ring due to one of the above misalignments. There is then a possibility that process gas is diluted to varying degrees at different points of the gap by purge gas that is directed along the lower side of the susceptor, with the result that the thickness of the epitaxial layer and the distribution of dopants in the epitaxial layer may vary along the circumferential direction of the substrate wafer.

The above-mentioned misalignments can already exist in the cold state of the deposition device or may only occur during the course of the heating of the deposition device to operating temperature, and possibly disappear again in the process of cooling to the cold state, for example when cooling to room temperature.

It is therefore proposed to monitor whether at least one of the misalignments is present and, if necessary, to correct the misalignment. For this purpose, in principle, the deposition device can be cooled to ambient temperature and the respective misalignment can be eliminated.

In cases where this is possible, it is preferably carried out by moving the support shaft with the deposition device closed. In other cases, the deposition device is opened and the cause of the misalignment is corrected. If, for example, the susceptor is misaligned because the susceptor is positioned horizontally on the support arms of the support shaft but eccentrically with respect to the pre-heating ring, or because the susceptor is positioned on the support arms of the support shaft concentrically with the pre-heating ring, but tilted out of the horizontal position, the deposition device is opened, the susceptor is raised and placed as intended on the support arms of the support shaft.

In cases where it is possible to correct the misalignment by moving the support shaft, the deposition device remains closed and cooling of the deposition device to ambient temperature is unnecessary. If the reaction chamber of the deposition device is already in a hot state, which is the case at least at a temperature of 450° C. and higher, when a misalignment of the support shaft occurs, the misalignment is preferably corrected without cooling the deposition device below the specified temperature of 450° C., more preferably without lowering the temperature attained in the deposition device. A misalignment of the support shaft can be corrected by moving the support shaft if the reason for the misalignment is that the support shaft is vertical, but not aligned along the vertical axis through the center of the pre-heating ring, or because the support shaft is tilted out of the vertical axis through the center of the pre-heating ring.

The arrangement of the susceptor and the supporting shaft with respect to their position relative to the position of the pre-heating ring is observed by means of a camera system which captures an image excerpt that extends radially, preferably over at least one region which encloses a section of the circumference of the substrate wafer and a section of the inner circumference of the pre-heating ring. This image excerpt also includes a section of the gap between the susceptor and the pre-heating ring. The image excerpt recorded by the camera system has an azimuthal width of preferably not less than 12°. The positions of the sections are identified by an image processing device from characteristic contrast differences, along with the distance of the camera system preferably to the upper face of the susceptor, or the change in this distance. Where appropriate, a lighting system comprising one or more LED lamps, for example, may be provided to illuminate the reaction chamber while the deposition device is in the cold state. During the rotation of the support shaft, the image excerpt is recorded and evaluated at fixed intervals. From temporal changes of the said positions relative to each other and from temporal fluctuations of the said distance, the image processing device determines whether the above-mentioned misalignments of the susceptor and/or the support shaft are present. Based on the result of the determination, a control device generates control signals in order to set a drive unit for displacing and tilting the support shaft in motion, with the aim of eliminating an existing misalignment by moving the support shaft.

For example, the image processing device can use the algorithm described in US2016 0 125 589 A1, or preferably perform an image processing that uses the Sobel operator for edge detection.

The camera system comprises at least one camera, or preferably at least two cameras, which record two image excerpts with an azimuthal distance of 90° to each other. It is advantageous to store the data from the evaluation by means of the image processing device for comparison purposes, these data being obtained when the deposition device is in the cold state and none of the above-mentioned misalignments is present. In particular, it is advantageous to evaluate the respective image excerpt with respect to the width of the gap between the susceptor and the pre-heating ring when the supporting shaft and the susceptor are arranged as intended, and to store the width of the gap.

The lower dome of the deposition device and the drive unit are preferably connected via a bellows, so that a displacement and/or tilting movement of the support shaft relative to the stationary lower dome can be initiated when necessary without the ambient atmosphere reaching the support shaft.

In order to dampen vibrations, it is preferable to attach an upper end of a support arm to the outside of the so-called “base ring”, which keeps the upper and lower dome apart, and to mount the lower end of this support arm on the drive device for displacing and tilting the support shaft.

The drive device for displacing and tilting the support shaft of the susceptor comprises at least the necessary number of actuators in order to be able to displace the support shaft in the x-direction and in the y-direction and to tilt the support shaft about a rotational axis parallel to the x-direction and about a rotational axis parallel to the y-direction. Accordingly, four actuators are provided, for example, each of which causes one of the movements. The actuators are preferably piezoelectric actuating elements.

If the misalignment occurs when the deposition device is in the heated state, the above-mentioned misalignments are corrected by moving the support shaft, preferably also when the deposition device is heated and closed.

If the support shaft is in fact vertically aligned as intended, but not aligned along the vertical axis through the center of the pre-heating ring, and if the susceptor is positioned on the support arms as intended, when the susceptor rotates around the support shaft it will be observed that the width of the gap in the image excerpt of the camera system differs from the expected stored width, or, if the camera system comprises two cameras arranged at an azimuthal distance of 90°, that the observed width of the gap is different. In this case, a misalignment of the support shaft exists with respect to its position relative to the position of the pre-heating ring. It is corrected by displacing the support shaft horizontally into the position along the vertical axis through the center of the pre-heating ring.

If the support shaft is aligned as intended along the vertical axis through the center of the pre-heating ring and the susceptor is indeed positioned concentrically relative to the position of the pre-heating ring but tilted out of the horizontal on the support arms, during the rotation of the susceptor around the support shaft it will be observed that the distance from the camera system to the susceptor in the image excerpt of the camera varies sinusoidally over the course of the observation. This misalignment of the susceptor is corrected by restoring the susceptor to the intended position.

If the susceptor is in fact positioned on the support arms as intended, but the support shaft is tilted away from the intended alignment along the vertical axis through the center of the pre-heating ring, then a misalignment of the support shaft is also present with respect to its position relative to the position of the pre-heating ring. In this case, it is found that the observed width of the gap between the susceptor and the pre-heating ring differs from the width of the gap that was observed and stored when the support shaft and the susceptor were positioned as intended. This misalignment of the support shaft is corrected by tilting the support shaft into the intended position along the vertical axis through the center of the pre-heating ring, so that the observed width of the gap corresponds to the stored width of the gap.

For example, it may sometimes be the case that no misalignment is present in the cold state of the deposition device, i.e. the support shaft is aligned as intended along the vertical axis through the center of the pre-heating ring and the susceptor is positioned on the support arms horizontally and concentrically relative to the position of the pre-heating ring, and a misalignment of the support shaft only develops during the heating of the deposition device by the support shaft tilting out of the intended position.

The invention can be applied regardless of whether the substrate wafer is loaded into the deposition device alone or together with the susceptor. Preferably, the method according to the invention is applied in the closed deposition device and at an operating temperature of at least 450° C.

The susceptor has a circular outer circumference in plan view and preferably has a pocket and a placement surface, on which the substrate wafer rests in the edge region of its rear face. The substrate wafer is preferably placed on the placement surface in such a way that there is a distance between the rear face of the substrate wafer and a base that forms the boundary of the pocket. Holes may be incorporated in the bottom of the pocket to facilitate the transport of dopants from the rear face of the substrate wafer into the reaction chamber under the susceptor. Instead of the holes, the base can be made of fibrous material which, due to the porosity of the material, can ensure the transport of dopants.

A substrate wafer preferably consists of single-crystalline silicon, as does the epitaxial layer which is deposited on the front face of the substrate wafer. The diameter of the substrate wafer is preferably at least 200 mm, particularly preferably at least 300 mm.

The invention preferably also comprises features known to the person skilled in the art in order to determine and correct a misalignment of the substrate wafer with respect to its position relative to the position of the susceptor.

The invention is described below with reference to drawings of an exemplary embodiment.

### LIST OF REFERENCE NUMERALS USED IN THE DRAWINGS

1 substrate wafer
2 susceptor
3 pre-heating ring
4 placement surface
5 gap
6 image excerpt
7 camera system
8 image processing device
9 support shaft
10 support arm
11 lifting shaft
12 drive unit
13 actuator (x-direction)
14 actuator (y-direction)
15 actuator (tilt angle φ)
16 actuator (tilt angle θ)
17 upper dome
18 lower dome
19 lamp bank
20 deposition device
21 control device
22 vertical axis
23 rear side
24 base
25 bellows

### DESCRIPTION OF AN EXEMPLARY EMBODIMENT

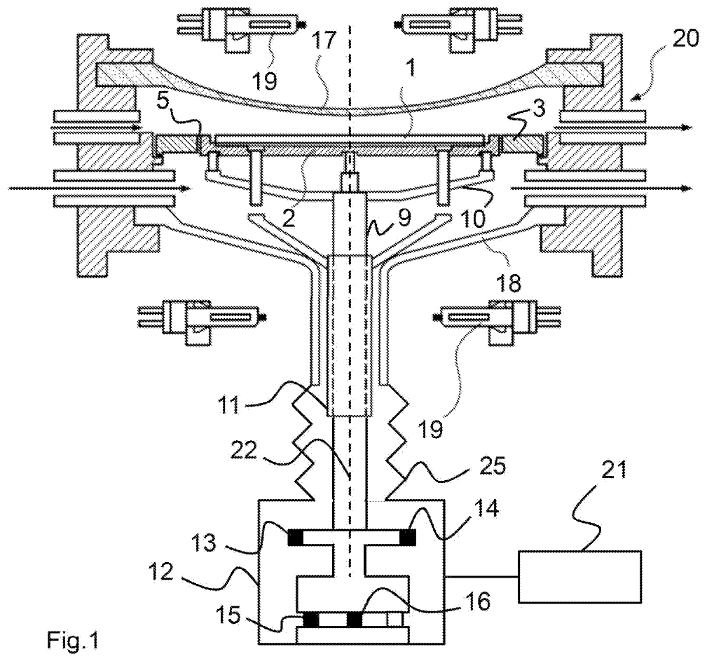

The reaction chamber of the deposition device 20 shown in FIG. 1 is bounded from above by an upper dome 17 and from below by a lower dome 18. A support shaft 9 protrudes into the center of the reaction chamber, with support arms 10 branching off from said shaft at an upper end. The support arms 10 support a susceptor 2, on which a substrate wafer 1 rests during the deposition of an epitaxial layer. In the embodiment shown, it is provided to place the substrate wafer 1 on a lifting shaft 11 during the loading of the deposition device 20 and to place it onto the susceptor by lowering the lifting shaft 11. The deposition gas is directed via a front face of the substrate glass facing the upper dome 17 from a gas inlet to a gas outlet, both of which are located on a side wall of the deposition device. A pre-heating ring 3 is arranged between the side wall of the deposition device and the susceptor 2. In addition, a corresponding gas inlet and gas outlet can be provided for purge gas which is directed under the susceptor and through the reaction chamber, parallel to its side facing downwards. Arrows indicate the flow direction of the gas streams. The reaction chamber is heated from the outside by lamp banks 19, which irradiate radiant energy through the upper and lower domes 17 and 18.

In the intended arrangement of the susceptor 2 with respect to its position relative to the position of the pre-heating ring 3 surrounding it, a gap 5 is provided between the pre-heating ring 3 and the susceptor 2, the width of which is constant along the outer circumference of the susceptor and the inner circumference of the pre-heating ring. The axis through the center of the susceptor 2 and the vertical axis 22 through the center of the pre-heating ring 3 are coincident. In the intended arrangement of the support shaft 9 with respect to its position relative to the position of the pre-heating ring 3, the gap 5 along the outer circumference of the susceptor 2 and the inner circumference of the pre-heating ring has a constant width, and when the support shaft rotates the rotation axis of the rotation and the vertical axis 22 are coincident.

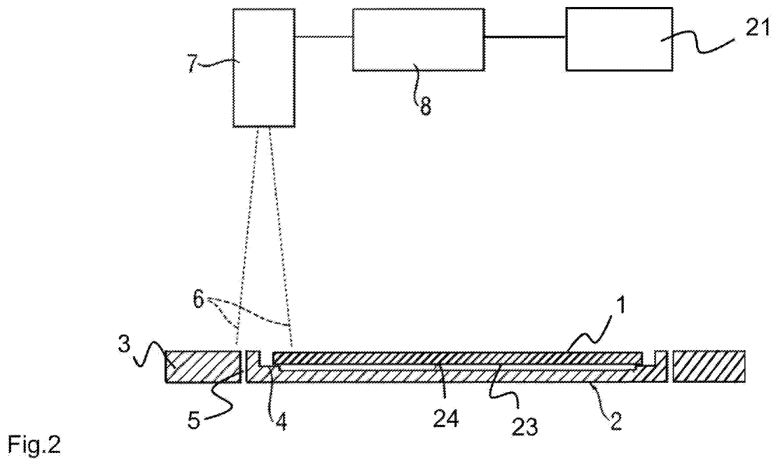

A misalignment of the susceptor 2 with respect to its position relative to the position of the pre-heating ring 3 surrounding it is present if the susceptor 2 is positioned horizontally on the support arms 10 but eccentrically with respect to the pre-heating ring, or if the susceptor 2 is not positioned horizontally on the support arms 10, i.e. is located in a plane that is not aligned orthogonally to the vertical axis 22. Then, in the first case the observed width of the gap 5 between the susceptor 2 and the pre-heating ring 3 changes, and in the second case the distance from the susceptor 2 to a camera system 7 varies (FIG. 2), with which the width of the gap 5 is observed when the susceptor 2 is rotated by means of the support shaft 9.

A misalignment of the support shaft 9 with respect to its position relative to the position of the pre-heating ring 3 surrounding it is present if the observed width of the gap 5 between the susceptor 2 and the pre-heating ring 3 varies because the support shaft 9 is oriented vertically, but not along the vertical axis 22 through the center of the pre-heating ring 3. A misalignment of the support shaft 9 with respect to its position relative to the position of the pre-heating ring 3 surrounding it is also present if the observed width of the gap 5 has changed compared to a stored width of the gap 5 because the support shaft 9 is tilted out of the intended position, i.e. if the rotational axis of the support shaft 9 and the vertical axis 22 are not arranged parallel through the center of the pre-heating ring 3 when the susceptor 2 rotates.

The camera system 7 shown in FIG. 2 comprises a camera for observing an image excerpt 6 during the rotation of the susceptor 2 by means of the support shaft 9. The image excerpt 6 captures a radially extending region which preferably encloses a section of the outer circumference of the substrate wafer 1, a section of the outer circumference of the susceptor 2, and a section of the inner circumference of the pre-heating ring 3 and thus also a section of the gap 5 between the susceptor 2 and the pre-heating ring 3. The substrate wafer 1 is located in a pocket of the susceptor 2 on a placement surface 4, so that the rear side 23 of the substrate wafer 1 is a distance away from the base 24 of the susceptor 2. The information contained in the image excerpt 6 is evaluated by means of the image processing device 8, in particular with regard to the width of the gap 5 and the distance from the camera system 7 to the susceptor 2. The control device 21 is used to check whether a misalignment of the susceptor 2 and/or the support shaft 9 is present and, as necessary, if a misalignment of the support shaft 9 exists it generates a signal that sets the drive device 12 (FIG. 1) into motion that corrects the existing misalignment of the support shaft. If a misalignment of the susceptor is present, the deposition device is brought to ambient temperature if necessary and opened, and the misalignment is corrected.

The drive device 12 has the special property of being able to displace or tilt the support shaft 9, and of course both at the same time. A possible embodiment of the drive device 12 is shown in FIG. 1. The movement of the support shaft 9 is triggered by actuators such as piezoelectric actuators. For displacing the support shaft 9 in the horizontal plane, actuators 13 (for displacement in the x-direction) and 14 (for displacement in the y-direction) are provided, and actuator 16 is provided for tilting the support shaft 9 from the viewing plane of FIG. 1 about a rotational axis parallel to the x-direction with a tilting angle φ and actuator 15 for tilting the support shaft 9 in the viewing plane of FIG. 1 about a rotational axis parallel to the y-direction with a tilting angle θ.

The lower dome 18 of the deposition device 20 is connected to the drive device 12 by means of a bellows 25, in order to enable the movement of the support shaft 9 and to seal the internal space created thereby against the inflow of ambient atmosphere.

1.-4. (canceled)

5. A method for depositing an epitaxial layer on a substrate wafer of semiconductor material, comprising:
arranging the substrate wafer and a susceptor in a deposition device having a rotatable support shaft with arms for holding the susceptor and a preheating ring located around the susceptor and spaced apart therefrom, such that the substrate wafer rests on the susceptor and the susceptor is held by arms of the support shaft;
monitoring whether a misalignment of the susceptor with respect to its position relative to the position of the pre-heating ring surrounding it exists;
monitoring whether a misalignment of the support shaft with respect to its position relative to the position of the pre-heating ring exits;
if at least one of the misalignment is present, correcting the respective misalignment at a temperature of not less than 450° C. by means of a control device which sets a drive unit for displacing and tilting the support shaft in motion; and depositing the epitaxial layer on the substrate wafer.

6. A method according to claim 5, wherein correcting the at least one misalignment occurs while the deposition device is closed.
